(19) United States
(12) Patent Application Publication
(10) Pub. No.: US 2026/0271646 A1
(43) Pub. Date: Sep. 10, 2026

(54) GRINDING DEVICE AND SEMICONDUCTOR DEVICE MANUFACTURING METHOD

(71) Applicant: Kioxia Corporation, Tokyo (JP)

(72) Inventor: Tomonori KAWASAKI, Yokkaichi (JP)

(73) Assignee: Kioxia Corporation, Tokyo (JP)

(21) Appl. No.: 19/331,714

(22) Filed: Sep. 17, 2025

(30) Foreign Application Priority Data
Mar. 6, 2025 (JP) 2025-035833

(51) Int. Cl. H01L 21/304; B24B 9/06; H01L 21/768; H01L 23/00

(52) U.S. Cl. CPC H10P 52/00; B24B 9/065; H10W 20/043; H10W 80/312; H10W 80/327

(57) ABSTRACT

A grinding device includes a blade having a disc shape, configured to grind an outer peripheral portion of a semiconductor substrate that rotates with respect to a first axis, and rotating with respect to a second axis, the first axis intersecting the second axis. The blade has a blade face including an outer peripheral edge portion that comes into contact with the outer peripheral portion of the semiconductor substrate. At least the outer peripheral edge portion of the blade face is inclined to the first axis.

### CROSS-REFERENCE TO RELATED APPLICATION(S)

This application is based upon and claims the benefit of priority from Japanese Patent Application No. 2025-035833, filed Mar. 6, 2025, the entire contents of which are incorporated herein by reference.

### FIELD

Embodiments described herein relate generally to a grinding device, and to a semiconductor device manufacturing method.

### BACKGROUND

When trimming an outer peripheral portion of a wafer using a grinding device that includes a blade, damage, which is also called chipping, may occur in the outer external peripheral portion of the wafer. When chipping occurs, forming a bonding pad on the wafer is difficult.

### DESCRIPTION OF THE DRAWINGS

FIG. 1 is a drawing showing an example of a configuration of a grinding device according to a first embodiment.

FIG. 2 is a sectional view showing a blade of the grinding device according to the first embodiment.

FIG. 3 is a plan view showing the blade of the grinding device according to the first embodiment.

FIG. 4 is a flowchart showing a semiconductor device manufacturing method according to the first embodiment.

FIGS. 5A to 5C, continuing from FIG. 4, are sectional views showing a semiconductor device manufacturing method according to the first embodiment.

FIGS. 6A and 6B are sectional views showing a semiconductor device manufacturing method according to a comparative example.

FIG. 7 is a sectional view showing a semiconductor device manufactured using a semiconductor manufacturing method according to a second embodiment.

FIGS. 8A to 8I are sectional views showing a semiconductor manufacturing method according to the second embodiment.

FIG. 9 is a sectional view showing a semiconductor device manufactured using a semiconductor manufacturing method according to a third embodiment.

FIGS. 10A to 10I are sectional views showing a semiconductor manufacturing method according to the third embodiment.

### DETAILED DESCRIPTION

Embodiments provide a grinding device and a semiconductor device manufacturing method such that an effect of chipping occurring due to grinding an outer peripheral portion of a semiconductor device can be alleviated.

In general, according to one embodiment, a grinding device includes a blade having a disc shape, configured to grind an outer peripheral portion of a semiconductor substrate that rotates with respect to a first axis, and rotating with respect to a second axis, the first axis intersecting the second axis. The blade has a blade face including an outer peripheral edge portion that comes into contact with the outer peripheral portion of the semiconductor substrate. At least the outer peripheral edge portion of the blade face is inclined to the first axis.

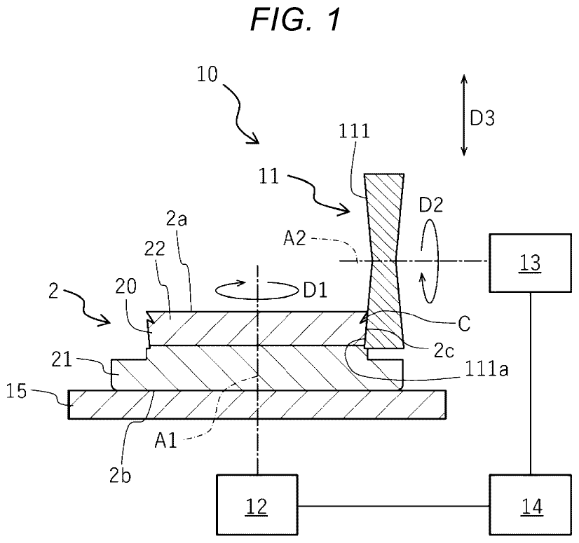

Hereafter, embodiments of the present application will be described, with reference to the drawings. In FIGS. 1 to 10, identical reference signs are allotted to identical or similar configurations, and redundant descriptions are omitted.

### First Embodiment

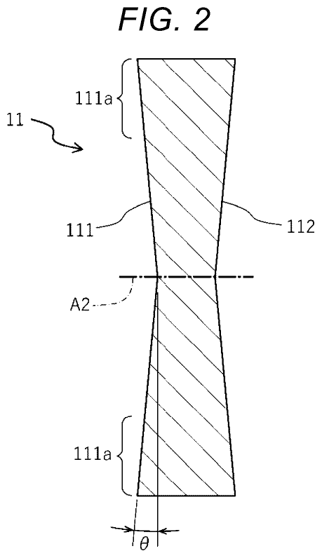

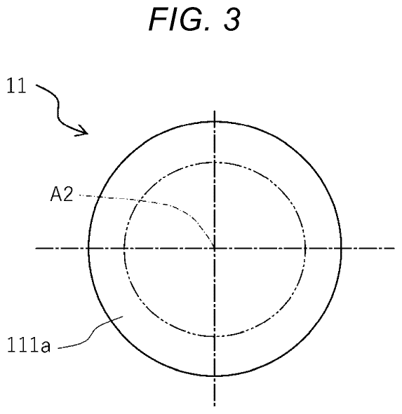

FIG. 1 is a drawing showing an example of a configuration of a grinding device 10 according to a first embodiment. FIG. 2 is a sectional view showing a blade 11 of the grinding device 10 according to the first embodiment. FIG. 3 is a plan view showing the blade 11 of the grinding device 10 according to the first embodiment.

The grinding device 10 is also called a trimming device. In the example shown in FIG. 1, the grinding device 10 includes the blade 11, a first drive unit 12, a second drive unit 13, a drive control unit (or controller) 14, and a holding table 15. The drive control unit 14 is one example of a control unit.

The blade 11 rotates with respect to a wafer 2, which rotates centered on a first axis of rotation A1, centered on a second axis of rotation A2 that intersects the first axis of rotation A1, and grinds an outer peripheral portion 20 of the wafer 2. The wafer 2 is one example of a semiconductor substrate. The blade 11 has a disc form. As shown in FIG. 3, the blade 11 has a circular form when seen from an axial direction of the second axis of rotation A2. The blade 11 is configured of, for example, a grindstone such that an abrasive grain such as a diamond is combined with a bonding material such as a resin.

The blade 11 has a blade face 111 including an outer peripheral edge portion 111a that can come into contact with the outer peripheral portion 20 of the wafer 2. Of the blade face 111, at least the outer peripheral edge portion 111a is inclined to the first axis of rotation A1 side (that is, a center of the wafer 2) while progressing outward in a radial direction from a center of the blade face 111. As the outer peripheral edge portion 111a is inclined to the first axis of rotation A1 side while progressing outward in a radial direction, an effect of a chipping C shown in FIG. 1 occurring because of grinding of the outer peripheral portion 20 of the wafer 2 can be alleviated. Specifically, an effect of the chipping C on a formation of a wiring layer (that is, a bonding pad) of the wafer 2 can be alleviated, as will be described hereafter.

In the example shown in FIG. 1, the wafer 2 is held on the holding table 15, which can rotate in a D1 direction centered on the first axis of rotation A1, which follows a vertical direction. The wafer 2 is held on the holding table 15 by, for example, adsorption (that is, intake suctioning) by a vacuum pump. The wafer 2 is rotated integrated with the holding table 15 in accordance with a rotation of the holding table 15. The holding table 15 is driven in such a way as to rotate by the first drive unit 12. The first drive unit 12 has a driving source such as a motor.

In the example shown in FIG. 1, the blade 11 can rotate in a D2 direction centered on the second axis of rotation A2, which is perpendicular to the first axis of rotation A1 in a horizontal direction. The blade 11 is driven in such a way as to rotate by the second drive unit 13. The second drive unit 13 has a driving source such as a motor.

In the example shown in FIG. 1, the wafer 2 has a substrate 21, and an upper layer 22 provided on the substrate 21. The substrate 21 is, for example, a silicon substrate. The upper layer 22 includes, for example, a memory cell array. The upper layer 22 may also include a layered structure of a layer having a memory cell array and a layer having a circuit that controls the memory cell array. In the example shown in FIG. 1, the wafer 2 has a first face 2a (that is, an upper face of the upper layer 22), a second face 2b (that is, a lower face of the substrate 21) opposing the first face 2a, and the outer peripheral portion 20, which connects the first face 2a and the second face 2b. The blade 11 grinds mainly the outer peripheral portion 20 of the upper layer 22.

In the example shown in FIG. 2, the blade face 111 as a whole is inclined to the first axis of rotation A1 side while progressing outward in a radial direction from the center of the blade face 111. In other words, the blade face 111 has an approximately conical form. As the blade face 111 as a whole is inclined, a form of the blade face 111 can be simplified.

The outer peripheral edge portion 111a may pass through a central point of the blade face 111, and have an angle of inclination of 15° or more, 20° or less with respect to a reference plane perpendicular to the second axis of rotation A2. When the angle of inclination of the outer peripheral edge portion 111 a is less than 15°, alleviating the effect of the chipping C is difficult. Meanwhile, when the angle of inclination of the outer peripheral edge portion 111a exceeds 20°, the wafer 2 decreases in size, and the number of chips (that is, semiconductor devices) obtained decreases.

In the example shown in FIG. 2, the blade 11 has a progressively tapered form such that a thickness in a direction following the second axis of rotation A2 increases monotonically while progressing outward in a radial direction from the center. That is, a face 112 on a side opposite to that of the blade face 111 is inclined to a side opposite to that of the first axis of rotation A1 while progressing outward in a radial direction from the center. It may be arranged that the face 112 on the side opposite to that of the blade face 111 can be used in grinding the wafer 2 by changing an orientation of the blade 11.

Furthermore, the blade 11 can move up and down with respect to the wafer 2. In the example shown in FIG. 1, the blade 11 is driven in an up-down direction D3 by the second drive unit 13.

The drive control unit 14 controls a rotation of the wafer 2 by controlling the first drive unit 12. The drive control unit 14 controls a rotation of the blade 11 and an up-down movement of the blade 11 by controlling the second drive unit 13.

In a state in which rotation of the wafer 2 is caused to stop, the drive control unit 14 causes the blade 11 to descend to a grinding starting place on the outer peripheral portion 20 of the wafer 2 while causing the blade 11 to rotate, and carries out grinding of the outer peripheral portion 20 in the grinding starting place. After the grinding of the outer peripheral portion 20 in the grinding starting place is finished, the drive control unit 14 causes the wafer 2 to rotate while causing the blade 11 to rotate, in such a way that the outer peripheral portion 20 is ground over a whole periphery. The drive control unit 14 grinds the grinding starting place again owing to the rotation of the wafer 2 after the grinding when the blade 11 descends. Because of this, the grinding starting place can be ground to a form the same as that of other places.

The wafer 2 is held on the holding table 15 with a first face 2a (that is, a bonding face) to be bonded to a second wafer oriented upward, and a second face 2b on a side opposite to that of the first face 2a oriented downward. As shown in FIG. 1, the blade 11 grinds the outer peripheral portion 20 of the wafer 2 in such a way that an outer peripheral face 2c that inclines to the center (that is, the first axis of rotation A1 side) of the wafer 2 while progressing from the first face 2a toward the second face 2b is formed on the wafer 2.

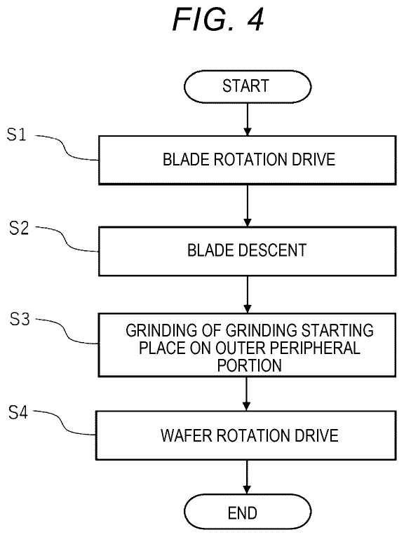

Next, a semiconductor device manufacturing method in which the grinding device 10 configured as heretofore described is used will be described. FIG. 4 is a flowchart showing a semiconductor device manufacturing method according to the first embodiment. In an initial state in FIG. 4, the wafer 2 is held by adsorption on the holding table 15. More specifically, the wafer 2 is held on the holding table 15 with the first face 2a oriented upward and the second face 2b oriented downward. Also, in the initial state in FIG. 4, rotation of both the holding table 15 and the blade 11 is stopped. Also, in the initial state in FIG. 4, the blade 11 is withdrawn upward with respect to the outer peripheral portion 20 of the wafer 2.

Further, from the initial state, the second drive unit 13 drives the blade 11 in such a way as to rotate in accordance with a control by the drive control unit 14, as shown in FIG. 4 (step S1).

After driving the blade 11 in such a way as to rotate, the second drive unit 13 causes the blade 11 to descend in accordance with a control by the drive control unit 14 (step S2). That is, in a state in which rotation of the wafer 2 is caused to stop, the drive control unit 14 causes the blade 11 to descend to a grinding starting place on the outer peripheral portion 20 of the wafer 2 while causing the blade 11 to rotate. Because of this, the blade 11 firstly grinds the outer peripheral portion 20 of the wafer 2 in the grinding starting place.

After grinding of the outer peripheral portion 20 in the grinding starting place is finished, the first drive unit 12 drives the wafer 2 in such a way as to rotate together with the holding table 15 in accordance with a control by the drive control unit 14 (step S4). That is, the drive control unit 14 causes the wafer 2 to rotate while causing the blade 11 to rotate. Because of this, the blade 11 grinds the outer peripheral portion 20 of the wafer 2 over the whole periphery.

When causing the wafer 2 to rotate while causing the blade 11 to rotate, the wafer 2 is held with the first face 2a (that is, the bonding face) upward, and the blade 11 is inclined to the first axis of rotation A1 side while progressing outward in a radial direction. Consequently, the blade 11 grinds the outer peripheral portion 20 of the wafer 2 in such a way that the wafer 2 has the outer peripheral face 2c, which inclines to the center of the wafer 2 while progressing from the first face 2a toward the second face 2b. That is, the blade 11 grinds the outer peripheral portion 20 of the wafer 2 in such a way as to have a reversely tapered form.

At this time, the drive control unit 14 causes the wafer 2 to rotate more than one turn by at least an amount equivalent to a length in a circumferential direction of the grinding starting place. By grinding the grinding starting place again, the outer peripheral portion 20 of the wafer 2 can be ground in such a way as to have the outer peripheral face 2c that also has a reversely tapered form in the grinding starting place, in the same way as in other places.

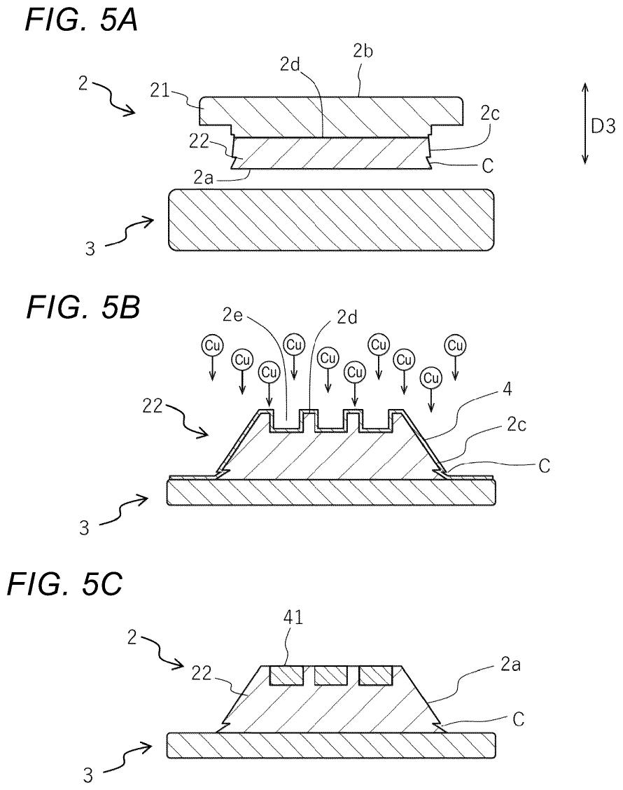

FIGS. 5A to 5C, continuing from FIG. 4, are sectional views showing a semiconductor device manufacturing method according to the first embodiment. After grinding the outer peripheral portion 20 of the wafer 2, the wafer 2 is bonded to a second wafer 3 via the first face 2a of the wafer 2 (FIG. 5A).

The second wafer 3 includes, for example, a memory cell array. In this case, a third wafer including a circuit that controls the memory cell array may be bonded to the second wafer 3 on a side opposite to that of the wafer 2. Alternatively, the second wafer 3 may include a layered structure of a layer having a memory cell array and a layer having a circuit that controls the memory cell array.

Bonding of the wafer 2 and the second wafer 3 is carried out via, for example, an unshown pad provided on the first face 2a of the wafer 2 and an unshown second pad provided on the second wafer 3 in such a way as to come into contact with the pad.

After bonding the wafer 2 to the second wafer 3 via the first face 2a, wiring is formed on the second face 2b side of the wafer 2.

When forming the wiring, firstly, the second face 2b is processed, causing a third face 2d to be exposed (FIG. 5B).

In the example shown in FIGS. 5A to 5C, the third face 2d is a surface of the upper layer 22 on a side opposite to that of the first face 2a. Exposure of the third face 2d is carried out by removing the substrate 21 using grinding, silicon wet etching, chemical mechanical polishing (CMP), or the like. After exposing the third face 2d, an aperture 2e in which wiring is provided is formed in the third face 2d (FIG. 5B). By forming the aperture 2e, for example, a plug provided in an interior of the upper layer 22 is exposed. Wiring formed in the aperture 2e is connected to the plug.

After the aperture 2e is formed, a seed layer 4 is formed on the third face 2d, on the outer peripheral face 2c of the wafer 2, and on a portion of the second wafer 3 exposed from the wafer 2 (FIG. 5B). Formation of the seed layer 4 is carried out using, for example, a physical vapor deposition (PVD). In the example shown, the seed layer 4 is a copper seed layer. The seed layer 4 may also be a seed layer other than a copper seed layer, such as a tungsten seed layer.

After forming the seed layer 4, a wiring layer 41 is formed on the seed layer 4 by a plating process using an unshown electrode formed on the second wafer 3 in such a way as to be connected to the seed layer 4 (FIG. 5C). The wiring layer 41 is, for example, a metal pad.

When grinding the outer peripheral portion 20 of the wafer 2 using the blade 11, the outer peripheral portion 20 is damaged by the blade 11. Owing to the damage, the chipping C is formed in the outer peripheral face 2c of the wafer 2. However, the chipping C formed in the outer peripheral face 2c, which has a reversely tapered form, is unlikely to come into the shade of the outer peripheral face 2c when inverting the wafer 2 and forming the seed layer 4 on the outer peripheral face 2c. “Unlikely to come into the shade” means that an interior of the chipping C is unlikely to be covered by the outer peripheral face 2c in a direction of progression of a material of the seed layer 4 when forming the seed layer 4. Owing to being unlikely to come into the shade, the seed layer 4 can be caused to enter a portion of the chipping C (FIG. 5B). By causing the seed layer 4 to enter a portion of the chipping C, the seed layer 4 can be formed seamlessly on the outer peripheral face 2c. As the seed layer 4 is formed seamlessly, electrons can be conveyed appropriately from the electrode side to the aperture 2e side via the seed layer 4 when carrying out the plating process (that is, an electrolytic plating). Because of this, the wiring layer 41 can be formed appropriately inside the aperture 2e (FIG. 5C).

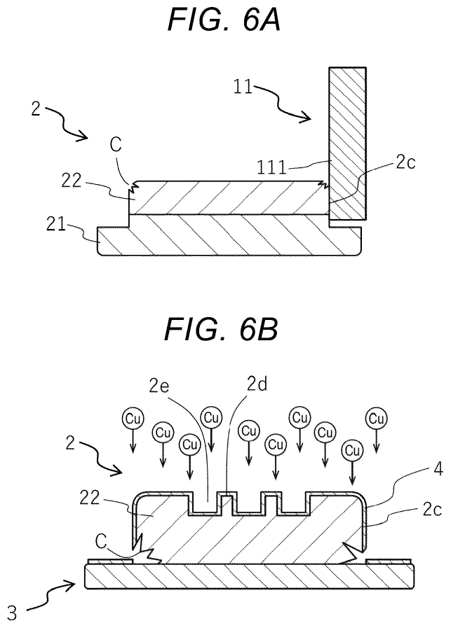

FIGS. 6A and 6B are sectional views showing a semiconductor device manufacturing method according to a comparative example. When grinding the outer peripheral portion 20 of the wafer 2 using the blade 11 such that the blade 111 face is not inclined, the chipping C formed in the outer peripheral face 2c is likely to come into the shade of the outer peripheral face 2c when inverting the wafer 2. Owing to being likely to come into the shade, causing the seed layer 4 to enter a portion of the chipping C is difficult (FIG. 6B). As causing the seed layer 4 to enter a portion of the chipping C is difficult, forming the seed layer 4 seamlessly on the outer peripheral face 2c is difficult. As forming the seed layer 4 seamlessly is difficult, conveying electrons from the electrode side to the aperture 2e side via the seed layer 4 when carrying out the plating process is difficult. Because of this, forming the wiring layer 41 appropriately inside the aperture 2e is difficult.

According to the first embodiment, as heretofore described, the outer peripheral edge portion 111a of the blade 111 is inclined to the first axis of rotation A1 side while progressing outward in a radial direction. As the outer peripheral edge portion 111a is inclined, the outer peripheral portion 20 of the wafer 2 can be ground by the blade 11 in such a way as to have the outer peripheral face 2c that has a reversely tapered form. The outer peripheral face 2c having a reversely tapered form means that even when the chipping C is formed in the outer peripheral face 2c, the chipping C is unlikely to come into the shade of the outer peripheral face 2c. Because of this, the seed layer 4 can be appropriately formed on the wafer 2 and on the second wafer 3 using a PVD. As the seed layer 4 is appropriately formed, a plating process using the seed layer 4 can be appropriately carried out, and the wiring layer 41 can be appropriately formed inside the aperture 2e. Consequently, according to the first embodiment, the effect of the chipping C occurring due to grinding the outer peripheral portion 20 of the wafer 2 can be alleviated.

### Second Embodiment

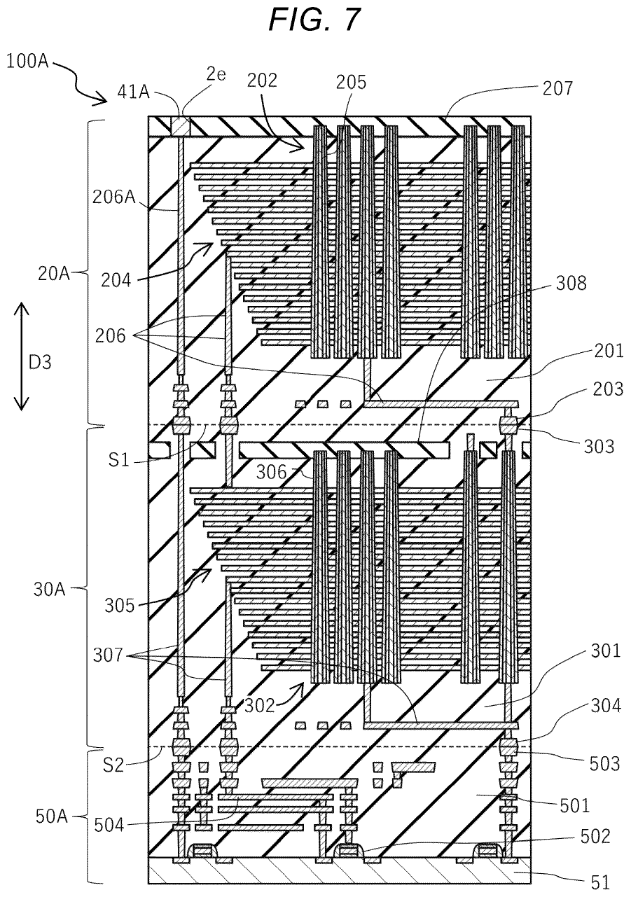

Next, a second embodiment that is more specific than the first embodiment will be described. FIG. 7 is a sectional view showing a semiconductor device 100A manufactured using a semiconductor manufacturing method according to a second embodiment. The semiconductor device 100A shown in FIG. 7 is a three-dimensional memory such that a first array chip 20A, a second array chip 30A, and a circuit chip 50A are bonded together. The semiconductor device 100A has a CMOS directly bonded to array (CBA) structure. A first array wafer before being divided into the first array chip 20A is one example of a first semiconductor substrate. A second array wafer before being divided into the second array chip 30A is one example of a second semiconductor substrate. A circuit wafer before being divided into the circuit chip 50A is one example of a third semiconductor substrate.

As shown in FIG. 7, the first array chip 20A is provided on the second array chip 30A. The circuit chip 50A is provided under the second array chip 30A. The first array chip 20A and the second array chip 30A are bonded together at a bonding face S1. The second array chip 30A and the circuit chip 50A are bonded together at a bonding face S2.

The first array chip 20A (that is, the first array wafer) includes an interlayer insulating film 201, a first memory cell array 202, a multiple of lower pads 203, an upper pad 41A, a multiple of wires 206 including a plug and a bit line, and an insulating layer 207. The interlayer insulating film 201 is one example of a first insulating film. The lower pad 203 is one example of a first pad. The upper pad 41A is one example of a fifth pad. The interlayer insulating film 201 is, for example, a silicon oxide film. The first memory cell array 202 is provided inside the interlayer insulating film 201. The first memory cell array 202 has a layered film 204, which has a graduated structure, and a multiple of columnar portions 205. The layered film 204 is a film in which a multiple of wiring layers and a multiple of insulating layers are stacked alternately. The wiring layer functions as a word line or a source line. The wiring layer contains, for example, tungsten. The insulating layer is, for example, a silicon oxide film. The columnar portion 205 is provided penetrating the layered film 204. The columnar portion 205 includes in order, for example, a block insulating film, a charge storage film, a tunnel insulating film, a channel semiconductor film, and a core insulating film inside a memory hole that penetrates the layered film 204. The lower pad 203 is provided inside the interlayer insulating film 201. The lower pad 203 is electrically connected to the first memory cell array 202 via the wire 206. The insulating layer 207 is provided on the interlayer insulating film 201.

The upper pad 41A is a specific example of the wiring layer 41 shown in FIGS. 5A to 5C. The upper pad 41A is provided penetrating the insulating layer 207 in such a way as to come into contact with a plug 206A provided inside the interlayer insulating film 201. More specifically, the upper pad 41A is provided in an interior of the aperture 2e, which penetrates the insulating layer 207. The upper pad 41A is electrically connected to the first memory cell array 202 via the wires 206 and 206A on a side opposite to that of the lower pad 203.

The second array chip 30A (that is, the second array wafer) includes an interlayer insulating film 301, a second memory cell array 302, a multiple of upper pads 303, a multiple of lower pads 304, a multiple of wires 307 including a plug and a bit line, and an insulating layer 308. The interlayer insulating film 301 is one example of a second insulating film. The upper pad 303 is one example of a second pad. The lower pad 304 is one example of a third pad. The second memory cell array 302 is provided inside the interlayer insulating film 301. The second memory cell array 302 has a layered film 305, which has a graduated structure, and a multiple of columnar portions 306. The layered film 305 is a film in which a multiple of wiring layers and a multiple of insulating layers are stacked alternately. The columnar portion 306 is provided penetrating the layered film 305. The columnar portion 306 includes in order, for example, a block insulating film, a charge storage film, a tunnel insulating film, a channel semiconductor film, and a core insulating film inside a memory hole that penetrates the layered film 305. The upper pad 303 is provided inside the interlayer insulating film 301 in such a way as to come into contact with the lower pad 203. The upper pad 303 is electrically connected to the second memory cell array 302 via the wire 307. The lower pad 304 is provided inside the interlayer insulating film 301 in such a way as to come into contact with the circuit chip 50A. The lower pad 304 is electrically connected to the second memory cell array 302 via the wire 307.

The circuit chip 50A (that is, the circuit wafer) includes an interlayer insulating film 501, a multiple of transistors 502, a multiple of pads 503, and a multiple of wires 504. The interlayer insulating film 501 is one example of a third insulating film. The transistor 502 is one example of a circuit. The pad 503 is one example of a fourth pad. The transistor 502 is provided inside the interlayer insulating film 501. The transistor 502 controls the first memory cell array 202 and the second memory cell array 302. The transistor 502 includes a gate electrode, which is provided across a gate insulating film on a substrate 51, and a source diffusion layer and drain diffusion layer formed on the substrate 51. The pad 503 is provided inside the interlayer insulating film 501 in such a way as to come into contact with the lower pad 304. The pad 503 is electrically connected to the transistor 502 via the wire 504.

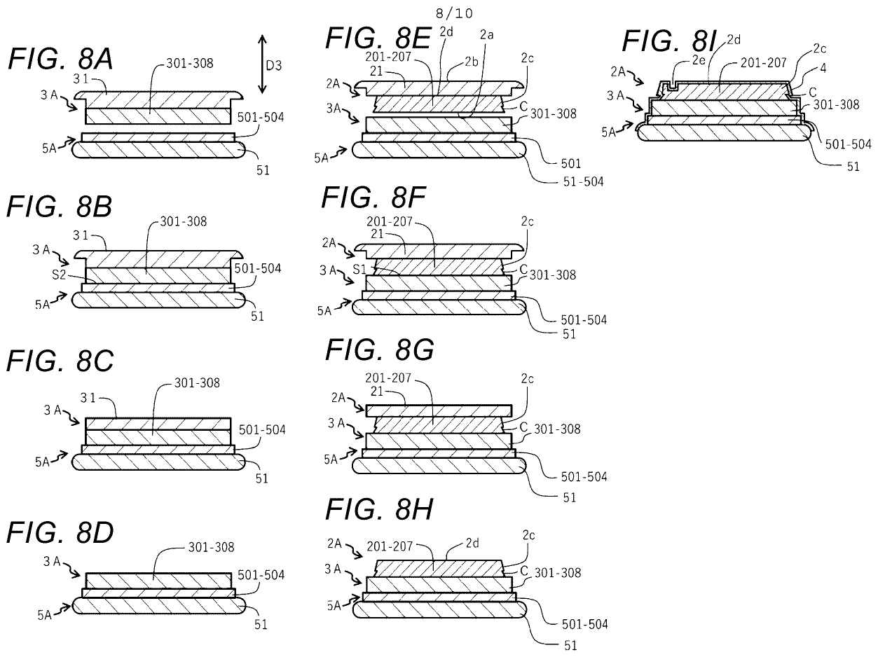

FIGS. 8A to 8I are sectional views showing a semiconductor device manufacturing method according to the second embodiment. In order to manufacture the semiconductor device 100A shown in FIG. 7, firstly, each of a second array wafer 3A and a circuit wafer 5A is prepared (FIG. 8A). The second array wafer 3A is a specific example of the second wafer 3 shown in FIGS. 5A to 5C. The circuit wafer 5A is one example of a third semiconductor substrate.

The second array wafer 3A is a wafer such that the interlayer insulating film 301, the second memory cell array 302, the upper pad 303, the lower pad 304, the wire 307, and the insulating film 308 are provided on a substrate 31. In FIGS. 8A to 8I, a depiction of the interlayer insulating film 301, the second memory cell array 302, the upper pad 303, the lower pad 304, the wire 307, and the insulating film 308 is simplified. Also, in FIGS. 8A to 8I, the second array wafer 3A is inverted for bonding to the circuit wafer 5A. In FIGS. 8A to 8I, positional relationships and orientations of the components 301 to 308 under the substrate 31 are the same as in FIG. 7.

The circuit wafer 5A is a wafer such that the interlayer insulating film 501, the transistor 502, the pad 503, and the wire 504 are provided on the substrate 51. In FIGS. 8A to 8I, a depiction of the interlayer insulating film 501, the transistor 502, the pad 503, and the wire 504 is simplified. In FIGS. 8A to 8I, positional relationships and orientations of the components 501 to 504 under the substrate 51 are the same as in FIG. 7.

After each of the second array wafer 3A and the circuit wafer 5A is prepared, the second array wafer 3A and the circuit wafer 5A are bonded together at the bonding face S2 (FIG. 8B). Specifically, as shown in FIG. 7, the second array wafer 3A and the circuit wafer 5A are bonded together in such a way that the lower pad 304 of the second array wafer 3A and the pad 503 of the circuit wafer 5A are joined together. An application of mechanical pressure or annealing is used for the bonding.

After the second array wafer 3A and the circuit wafer 5A are bonded together, the substrate 31 of the second array wafer 3A is thinned using a grinding process (that is, a backgrinding) (FIG. 8C).

After the substrate 31 of the second array wafer 3A is thinned, all of the substrate 31 of the second array wafer 3A is removed using a wet etching or CMP (FIG. 8D). As the substrate 31 is removed, the upper pad 303 (FIG. 7) is exposed in an upper face of the second array wafer 3A.

After all of the substrate 31 of the second array wafer 3A is removed, a first array wafer 2A is prepared (FIG. 8E). The first array wafer 2A may also be prepared before the substrate 31 is removed. The first array wafer 2A is a wafer such that the interlayer insulating film 201, the first memory cell array 202, the lower pad 203, the wire 206, and the insulating layer 207 are provided under the substrate 21 in FIGS. 8A to 8I. The interlayer insulating film 201, the first memory cell array 202, the lower pad 203, the wire 206, and the insulating layer 207 are a specific example of the upper layer 22 shown in FIGS. 1 and 5.

In FIGS. 8A to 8I, a depiction of the interlayer insulating film 201, the first memory cell array 202, the lower pad 203, the wire 206, and the insulating layer 207 is simplified. In FIGS. 8A to 8I, positional relationships and orientations of the components 201 to 207 under the substrate 21 are the same as in FIG. 7. In FIG. 8E, faces corresponding to the first face 2a, the second face 2b, the third face 2d, and the outer peripheral face 2c shown in FIGS. 5A to 5C are indicated by identical reference signs.

The outer peripheral face 2c of the first array wafer 2A (that is, an outer peripheral face of the interlayer insulating film 201) is ground by the blade 11 of the grinding device 10 in such a way as to have a reversely tapered form. This means that even when the chipping C occurs in the outer peripheral face 2c of the first array wafer 2A, the chipping C is unlikely to come into the shade of the outer peripheral face 2c. The first array wafer 2A shown in FIGS. 8A to 8I is inverted with respect to when grinding the outer peripheral portion 20 using the blade 11.

After the first array wafer 2A is prepared, the first array wafer 2A and the second array wafer 3A are bonded together at the bonding face S1 (that is, the first face 2a) (FIG. 8F). Specifically, as shown in FIG. 7, the first array wafer 2A and the second array wafer 3A are bonded together in such a way that the lower pad 203 of the first array wafer 2A and the upper pad 303 of the second array wafer 3A are joined together. An application of mechanical pressure or annealing is used for the bonding.

After the first array wafer 2A and the second array wafer 3A are bonded together, the substrate 21 of the first array wafer 2A is thinned using a grinding process (FIG. 8G).

After the substrate 21 of the first array wafer 2A is thinned, all of the substrate 21 of the first array wafer 2A is removed using a wet etching or CMP (FIG. 8H). As the substrate 21 is removed, an upper face of the insulating layer 207 shown in FIG. 7 is exposed. The upper face of the insulating layer 207 is a specific example of the third face 2d shown in FIGS. 5A to 5C.

After the substrate 21 of the first array wafer 2A is removed, the upper pad 41A shown in FIG. 7 is formed. Specifically, firstly, the aperture 2e that penetrates the insulating layer 207 shown in FIG. 7 is formed (FIG. 8I). As the aperture 2e is formed, an upper end of the plug 206A provided in an interior of the interlayer insulating film 201 shown in FIG. 7 is exposed.

After the aperture 2e is formed, the seed layer 4 is formed on an upper face of the insulating layer 207, on the outer peripheral face 2c of the first array wafer 2A, on a portion of the second array wafer 3A exposed from the first array wafer 2A, and on a portion of the circuit wafer 5A exposed from the first array wafer 2A and the second array wafer 3A (FIG. 8I).

After the seed layer 4 is formed, the upper pad 41A is formed on the seed layer 4 by a plating process in which the seed layer 4 is used (FIG. 7). After the upper pad 41A is formed, the semiconductor device 100A shown in FIG. 7 is obtained by dividing the bonded wafer into individual chips by dicing.

According to the second embodiment, the outer peripheral face 2c of the first array wafer 2A is formed in a reversely tapered form, meaning that even when the chipping C occurs in the outer peripheral face 2c, the chipping C is unlikely to come into the shade of the outer peripheral face 2c. As the chipping C is unlikely to come into the shade of the outer peripheral face 2c, the seed layer 4 can be appropriately formed on the outer peripheral face 2c. Because of this, a plating process in which the seed layer 4 is used can be appropriately carried out, and the upper pad 41A can be appropriately formed.

### Third Embodiment

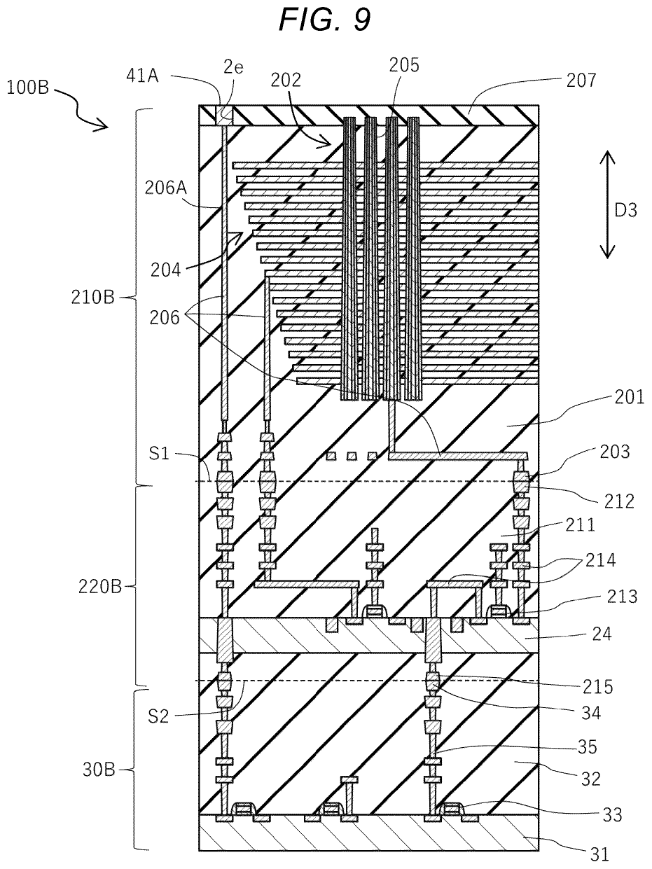

Next, a third embodiment, which is more specific than the first embodiment in a way differing from the second embodiment, will be described centering on differences from the heretofore described embodiments. FIG. 9 is a sectional view showing a semiconductor device 100B manufactured using a semiconductor manufacturing method according to a third embodiment. The semiconductor device 100B shown in FIG. 9 is a three-dimensional memory in which an array chip 210B, a first circuit chip 220B, and a second circuit chip 30B are bonded together. The semiconductor device 100B has a CBA structure. The bonded wafer before being divided into the array chip 210B and the first circuit chip 220B is one example of a semiconductor substrate. The first circuit chip 220B before being divided is one example of a first layer. The array chip 210B before being divided is one example of a second layer. The second circuit wafer before being divided into the second circuit chip 30B is one example of a second semiconductor substrate.

As shown in FIG. 9, the array chip 210B is provided on the first circuit chip 220B. The second circuit chip 30B is provided under the first circuit chip 220B. The array chip 210B and the first circuit chip 220B are bonded together at the bonding face S1. The first circuit chip 220B and the second circuit chip 30B are bonded together at the bonding face S2.

The array chip 210B includes the interlayer insulating film 201, the memory cell array 202, the multiple of lower pads 203, the upper pad 41A, the multiple of wires 206, and the insulating layer 207. The interlayer insulating film 201 is one example of a fourth insulating film. The memory cell array 202 is one example of a third memory cell array. The lower pad 203 is one example of a sixth pad. The upper pad 41A is one example of a tenth pad. The interlayer insulating film 201 is, for example, a silicon oxide film. The memory cell array 202 is provided inside the interlayer insulating film 201. The memory cell array 202 has the layered film 204, which has a graduated structure, and the multiple of columnar portions 205. The lower pad 203 is provided inside the interlayer insulating film 201. The lower pad 203 is electrically connected to the memory cell array 202 via the wire 206. The insulating layer 207 is provided on the interlayer insulating film 201.

The upper pad 41A is a specific example of the wiring layer 41 shown in FIGS. 5A to 5C. The upper pad 41A is provided penetrating the insulating layer 207 in such a way as to come into contact with the plug 206A provided inside the interlayer insulating film 201. More specifically, the upper pad 41A is provided in the interior of the aperture 2e that penetrates the insulating layer 207. The upper pad 41A is electrically connected to the memory cell array 202 via the wires 206 and 206A on a side opposite to that of the lower pad 203.

The first circuit chip 220B includes a substrate 24, an interlayer insulating film 211, a multiple of transistors 213, a multiple of upper pads 212, a multiple of wires 214 including a plug, and a multiple of lower pads 215. The interlayer insulating film 211 is one example of a fifth insulating film. The transistor 213 is one example of a second circuit. The upper pad 212 is one example of a seventh pad. The lower pad 215 is one example of an eighth pad. The transistor 213 is provided inside the interlayer insulating film 211. The transistor 213 controls the memory cell array 202. The transistor 213 includes a gate electrode, which is provided across a gate insulating film on the substrate 24, and a source diffusion layer and drain diffusion layer formed on the substrate 24. The upper pad 212 is provided inside the interlayer insulating film 211 in such a way as to come into contact with the lower pad 203 of the array chip 210B. The upper pad 212 is electrically connected to the transistor 213 via the wire 214. The lower pad 215 is provided inside the interlayer insulating film 211 under the substrate 24 in such a way as to come into contact with the second circuit chip 30B. The lower pad 215 is electrically connected to the memory cell array 202 via the wire 214.

The second circuit chip 30B includes an interlayer insulating film 32, a multiple of transistors 33, a multiple of pads 34, and a multiple of wires 35 including a plug. The interlayer insulating film 32 is one example of a sixth insulating film. The transistor 33 is one example of a third circuit. The pad 34 is one example of a ninth pad. The transistor 33 is provided inside the interlayer insulating film 32. The transistor 33 controls the memory cell array 202. The transistor 33 includes a gate electrode, which is provided across a gate insulating film on the substrate 31, and a source diffusion layer and drain diffusion layer formed on the substrate 31. The pad 34 is provided inside the interlayer insulating film 32 in such a way as to come into contact with the lower pad 215 of the first circuit chip 220B. The pad 34 is electrically connected to the transistor 33 via the wire 35.

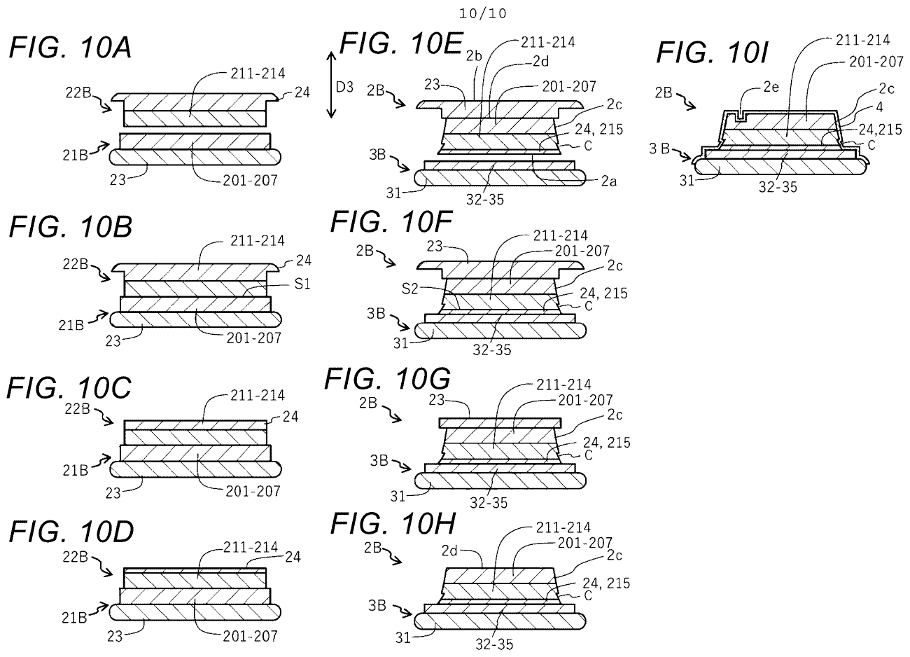

FIGS. 10A to 10I are sectional views showing a semiconductor device manufacturing method according to the third embodiment. In order to manufacture the semiconductor device 100B shown in FIG. 9, firstly, each of a first circuit wafer 22B and an array wafer 21B is prepared (FIG. 10A).

The first circuit wafer 22B is a wafer such that the interlayer insulating film 211, the transistor 213, the upper pad 212, and the wire 214 are provided on the substrate 24. In FIGS. 10A to 10I, a depiction of the interlayer insulating film 211, the transistor 213, the upper pad 212, and the wire 214 is simplified. Also, in FIG. 10A, the first circuit wafer 22B is inverted for bonding to the array wafer 21B. After being bonded to the array wafer 21B, the first circuit wafer 22B is inverted again for bonding to a second circuit wafer 3B, to be described hereafter. In FIG. 10A, positional relationships and orientations of the components 211 to 214 under the substrate 24 are inverted with respect to FIG. 9.

The array wafer 21B is a wafer such that the interlayer insulating film 201, the memory cell array 202, the lower pad 203, the wire 206, and the insulating layer 207 are provided on a substrate 23. In FIGS. 10A to 10I, a depiction of the interlayer insulating film 201, the memory cell array 202, the lower pad 203, the wire 206, and the insulating layer 207 is simplified. In FIG. 10A, positional relationships and orientations of the components 201 to 207 under the substrate 23 are inverted with respect to FIG. 9.

After each of the first circuit wafer 22B and the array wafer 21B is prepared, the first circuit wafer 22B and the array wafer 21B are bonded together at the bonding face S1 (FIG. 10B). Specifically, as shown in FIG. 9, the first circuit wafer 22B and the array wafer 21B are bonded together in such a way that the upper pad 212 of the first circuit wafer 22B and the lower pad 203 of the array wafer 21B are joined together. An application of mechanical pressure or annealing is used for the bonding.

After the first circuit wafer 22B and the array wafer 21B are bonded together, the substrate 24 of the first circuit wafer 22B is thinned using a grinding process (FIG. 10C).

After the substrate 24 of the first circuit wafer 22B is thinned, the substrate 24 of the first circuit wafer 22B is further thinned using a wet etching or CMP (FIG. 10D). In FIG. 10D, the transistor 213 is provided under the substrate 24. Next, the lower pad 215 is formed on the substrate 24. By so doing, a bonded wafer 2B including the first layers 211 to 214, 24, and 215 on the circuit side (the first face side) and the second layers 201 to 207 on the array side (the second face side) is formed. The bonded wafer 2B is one example of a semiconductor substrate.

After the bonded wafer 2B is formed, the outer peripheral portion 20 of the bonded wafer 2B is ground using the grinding device 10. That is, the outer peripheral portion 20 of the bonded wafer 2B is ground using the blade 11, which has a progressively tapered form, in such a way as to have the outer peripheral face 2c that has a reversely tapered form. The outer peripheral face 2c having a reversely tapered form means that even when the chipping C occurs in the outer peripheral face 2c, the chipping C is unlikely to come into the shade of the outer peripheral face 2c.

After the outer peripheral portion 20 of the bonded wafer 2B is ground, the second circuit wafer 3B is prepared (FIG. 10E). The second circuit wafer 3B may also be prepared before the outer peripheral portion 20 of the bonded wafer 2B is ground. The second circuit wafer 3B is one example of a second semiconductor substrate. The second circuit wafer 3B is a wafer such that the interlayer insulating film 32, the transistor 33, the pad 34, and the wire 35 are provided on the substrate 31. In FIGS. 10A to 10I, a depiction of the interlayer insulating film 32, the transistor 33, the pad 34, and the wire 35 is simplified. In FIGS. 10A to 10I, positional relationships and orientations of the components 32 to 35 on the substrate 31 are the same as in FIG. 9. In FIG. 10E, faces corresponding to the first face 2a, the second face 2b, the third face 2d, and the outer peripheral face 2c shown in FIGS. 5A to 5C are indicated by identical reference signs.

After the second circuit wafer 3B is prepared, the bonded wafer 2B and the second circuit wafer 3B are bonded together at the bonding face S2 (FIG. 10F). Specifically, as shown in FIG. 9, the bonded wafer 2B and the second circuit wafer 3B are bonded together in such a way that the lower pad 215 of the bonded wafer 2B and the pad 34 of the second circuit wafer 3B are joined together. An application of mechanical pressure or annealing is used for the bonding.

After the bonded wafer 2B and the second circuit wafer 3B are bonded together, the substrate 23 of the bonded wafer 2B is thinned using a grinding process (FIG. 10G).

After the substrate 23 of the bonded wafer 2B is thinned, all of the substrate 23 of the bonded wafer 2B is removed using a wet etching or CMP (FIG. 10H). As the substrate 23 is removed, an upper face of the insulating layer 207 shown in FIG. 9 is exposed. The upper face of the insulating layer 207 is a specific example of the third face 2d shown in FIGS. 5A to 5C.

After the substrate 23 of the bonded wafer 2B is removed, the upper pad 41A shown in FIG. 9 is formed. Specifically, firstly, the aperture 2e that penetrates the insulating layer 207 shown in FIG. 9 is formed (FIG. 10I). As the aperture 2e is formed, an upper end of the plug 206A provided in an interior of the interlayer insulating film 201 shown in FIG. 9 is exposed. After the aperture 2e is formed, the seed layer 4 is formed on an upper face of the insulating layer 207, on the outer peripheral face 2c of the bonded wafer 2B, and on a portion of the second circuit wafer 3B exposed from the bonded wafer 2B (FIG. 10I).

After the seed layer 4 is formed, the upper pad 41A is formed on the seed layer 4 by a plating process in which the seed layer 4 is used (FIG. 9). After the upper pad 41A is formed, the semiconductor device 100B shown in FIG. 9 is obtained by dividing the bonded wafer into individual chips by dicing.

According to the third embodiment, the outer peripheral face 2c of the bonded wafer 2B is formed in a reversely tapered form, meaning that even when the chipping C occurs in the outer peripheral face 2c, the chipping C is unlikely to come into the shade of the outer peripheral face 2c. As the chipping C is unlikely to come into the shade of the outer peripheral face 2c, the seed layer 4 can be appropriately formed on the outer peripheral face 2c. Because of this, a plating process in which the seed layer 4 is used can be appropriately carried out, and the upper pad 41A can be appropriately formed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A grinding device, comprising:
a blade having a disc shape, configured to grind an outer peripheral portion of a semiconductor substrate that rotates with respect to a first axis, and rotating with respect to a second axis, the first axis intersecting the second axis, wherein
the blade has a blade face including an outer peripheral edge portion that comes into contact with the outer peripheral portion of the semiconductor substrate, and
at least the outer peripheral edge portion of the blade face is inclined to the first axis.

2. The grinding device according to claim 1, wherein the blade face as a whole is inclined to the first axis.

3. The grinding device according to claim 1, wherein the outer peripheral edge portion of the blade face passes through a central point of the blade face, and has an angle of inclination equal to or greater than 15° and equal to or less than 20° respect to a reference plane perpendicular to the second axis.

4. The grinding device according to claim 1, wherein a thickness of the blade increases in a direction from the second axis.

5. The grinding device according to claim 1, wherein the blade is configured to move vertically with respect to the semiconductor substrate, and
the grinding device further comprises a controller configured to control a rotation of the semiconductor substrate, a rotation of the blade, and a vertical movement of the blade.

6. The grinding device according to claim 5, wherein, when the semiconductor substrate stops rotating, the controller is configured to cause the blade to descend to a grinding starting place on the outer peripheral portion of the semiconductor substrate while causing the blade to rotate, and after a grinding of the outer peripheral portion in the grinding starting place, the controller is configured to cause the semiconductor substrate to rotate while causing the blade to rotate, such that the outer peripheral portion is ground over a whole periphery.

7. The grinding device according to claim 1, wherein the semiconductor substrate is held with a first face to be bonded to a second semiconductor substrate oriented upward, and a second face on a side opposite to that of the first face oriented downward, and
the blade is configured to grind the outer peripheral portion of the semiconductor substrate, such that an outer peripheral face that inclines to the center of the semiconductor substrate while progressing from the first face toward the second face is formed on the semiconductor substrate.

8. A semiconductor device manufacturing method, comprising:
grinding, with a blade, an outer peripheral portion of a semiconductor substrate that rotates with respect to a first axis;
wherein the blade rotates with respect to a second axis, the first axis intersecting the second axis;
wherein the blade has a blade face including an outer peripheral edge portion that comes into contact with the outer peripheral portion of the semiconductor substrate, and at least the outer peripheral edge portion of the blade face is inclined to the first axis.

9. The semiconductor device manufacturing method according to claim 8, wherein the semiconductor substrate has a first face, a second face on a side opposite to that of the first face, and the outer peripheral portion, which connects the first face and the second face, and wherein when the semiconductor substrate is held with the first face oriented upward and the second face oriented downward, such that an outer peripheral face that inclines to the center of the semiconductor substrate while progressing from the first face toward the second face is formed on the semiconductor substrate.

10. The semiconductor device manufacturing method according to claim 9, further comprising bonding the semiconductor substrate to a second semiconductor substrate via the first face, and
forming a wire on the second face side.

11. The semiconductor device manufacturing method according to claim 10, wherein forming the wire includes
forming a third face by processing the second face;
forming a seed layer on the third face, on the outer peripheral face of the semiconductor substrate, and on a portion of the second semiconductor substrate exposed from the semiconductor substrate; and
forming a wiring layer on the seed layer using a plating process.

12. The semiconductor device manufacturing method according to claim 11, further comprising bonding a third semiconductor substrate to the second semiconductor substrate on a side opposite to that of the semiconductor substrate before bonding the semiconductor substrate to the second semiconductor substrate.

13. The semiconductor device manufacturing method according to claim 12, wherein the semiconductor substrate includes a first insulating film, a first memory cell array provided inside the first insulating film, and a first pad that is provided inside the first insulating film and is electrically connected to the first memory cell array,
the second semiconductor substrate includes a second insulating film, a second memory cell array provided inside the second insulating film, a second pad that is provided inside the second insulating film in such a way as to come into contact with the first pad and is electrically connected to the second memory cell array, and a third pad that is provided inside the second insulating film in such a way as to come into contact with the third semiconductor substrate and is electrically connected to the second memory cell array,
the third semiconductor substrate includes a third insulating film, a circuit that is provided inside the third insulating film and controls the first and second memory cell arrays, and a fourth pad that is provided inside the third insulating film in such a way as to come into contact with the third pad and is electrically connected to the circuit, and
formation of the wire includes forming a fifth pad that is electrically connected to the first memory cell array on a side opposite to that of the first pad.

14. The semiconductor device manufacturing method according to claim 11, wherein the semiconductor substrate has a first layer on the first face side and a second layer on the second face side.

15. The semiconductor device manufacturing method according to claim 14, wherein the second layer includes a fourth insulating film, a third memory cell array provided inside the fourth insulating film, and a sixth pad that is provided inside the fourth insulating film in such a way as to come into contact with the first layer and is electrically connected to the third memory cell array,
the first layer includes a fifth insulating film, a second circuit that is provided inside the fifth insulating film and controls the third memory cell array, a seventh pad that is provided inside the fifth insulating film in such a way as to come into contact with the sixth pad and is electrically connected to the second circuit, and an eighth pad that comes into contact with the second semiconductor substrate and is electrically connected to the third memory cell array,
the second semiconductor substrate includes a sixth insulating film, a third circuit that is provided inside the sixth insulating film and controls the third memory cell array, and a ninth pad that is provided inside the sixth insulating film in such a way as to come into contact with the eighth pad and is electrically connected to the third circuit, and
formation of the wire includes forming a tenth pad that is electrically connected to the third memory cell array on a side opposite to that of the sixth pad.
